(19) United States
(12) Patent Application Publication
(10) Pub. No.: US 2013/0072067 A1
(43) Pub. Date: Mar. 21, 2013

(54) PRINTED CIRCUIT BOARD AND WIRING METHOD OF PRINTED CIRCUIT BOARD

(71) Applicant: Hiroshi YAMAMOTO, Tokyo (JP)

(72) Inventor: Hiroshi YAMAMOTO, Tokyo (JP)

(73) Assignee: NEC CORPORATION, Tokyo (JP)

(21) Appl. No.: 13/614,554

(22) Filed: Sep. 13, 2012

(30) Foreign Application Priority Data
Sep. 16, 2011 (JP) 2011-202868

(51) Int. Cl. H01R 12/72; H05K 3/10

(52) U.S. Cl. 439/629; 29/846

(57) ABSTRACT

A printed circuit board includes a rigid substrate having a card edge connector part connected to a host board, a primary signal line configured to be connected to the card edge connector part on the rigid substrate, a connection pad configured to be connected to the primary signal line at an edge that is opposite to another edge to which the card edge connector part is connected and the connection pad is electrically connected to another substrate, and a lead wiring connected to the connection pad.

### CROSS-REFERENCE TO RELATED APPLICATION

Priority is claimed on Japanese Patent Application No. 2011-202868, filed Sep. 16, 2011, the content of which is incorporated herein by reference.

### BACKGROUND OF THE INVENTION

1. Field of the Invention

The present invention is related to a printed circuit board and a wiring method of a printed circuit board.

2. Description of Related Art

A printed circuit board and the wiring method of a printed circuit board, in which the printed circuit board includes plated lead lines used for signal lines laid toward inner part of the printed circuit board from respective contacts to a card edge connector, are known and which are described in Japanese Unexamined Patent Application Publication No. 2010-232579 (patent document 1).

The patent document 1 describes that inner plated lead lines and common inner plated lead lines to be connected to the inner plated lead lines are formed on a printed circuit board in which a plating process is performed for the inner plated lead lines and the common inner plated lead lines.

A printed circuit board and a wiring method of a printed circuit board having dummy terminals are known in which multiple terminals are disposed in parallel each other in a main area of the circuit board. The dummy terminals are disposed in both sides and near to the multiple terminals and are positioned outside of the outline of the main area of the circuit board. This is described, for example, in Japanese Unexamined Patent Application Publication No. H04-326590 (patent document 2).

Patent document 2 describes that the dummy terminals are formed, similarly to other terminals, by a patterning process with connected to plated lead lines via plated leads. The dummy terminals are removed by shape processing that is performed after plating process.

Recently, transceivers used for data transmission between pieces of equipment in a data center employ low cost electrical interconnections because the distance of data transmission is short.

However, wide band interconnections are required as the data centers become larger scale and more functional due to spread of internet.

Therefore, the electrical interconnections used so far require more power consumption to adapt to the wide band interconnections.

The wide band interconnections give an impact to the total power consumption of a data center, and the electric interconnections do not allow extending the data transmission distance more than a few meters because of the limitation of electrical data transmission. As a solution of those problems, the optical interconnection attracts attention.

Although a CXP transceiver (C: 12 in hexadecimal number system, X: extend, P: pluggable) is known as an optical transceiver for optical interconnections, it is not practical use because multiple transmitter/receiver ports are required in the CXP transceiver.

In general, an optical transceiver having a card edge connector requires gold plating with a predetermined thickness at a connector part as specified by Multi Source Agreement (MSA).

The thickness is required as a specification that improves the reliability of pluggable connectors. In order to adapt to the specification, gold electroplating is employed instead of using gold flash technique that is difficult to form thick gold plating. Although gold electroplating allows the formation of a thick plating, the plating process is performed while current is flowing. Therefore it is required to form wiring branching from actual signal lines as lead wiring to obtain current flow of plating.

It is possible for a transceiver to use the branch wiring (referred to as lead wiring in the following) for treating signals at a signal rate up to approximately 1 Gbps, in which signal quality degradation is very low. At a signal rate of approximately 10 Gbps, the branch wirings become stubs that cause substantial band degradation or signal quality degradation.

A printed circuit board and a wiring method of a printed circuit board are proposed in which lead wirings are connected to connectors of parts of a circuit board.

As shown in FIG. 5, a printed circuit board 500 includes a card edge connector part 502 at one end of a rigid substrate 501.

Terminals 504 and 505 out of multiple terminals 503, 504 and 505 are connected to first layer wiring 506 and 507 that are high frequency signal lines at an upper layer of the rigid substrate 501, in which the connections are made for each single channel of transmit/receive.

The first layer wiring 506 and 507 are disposed to be separated about 1 to 2 mm from a side frame part being next to the connector part of the rigid substrate 501.

A second layer wiring 508, which is a lead line, is connected perpendicularly to the first layer wiring 506 on a lower layer of the rigid substrate 501. A second layer wiring 509, which is a lead line, is connected perpendicularly to the first layer wiring 507 at a lower layer of the rigid substrate 501.

In this case, the second layer wirings 508 and 509 are connected near the connector end which is one end of the rigid substrate 501.

In this manner, with respect to the printed circuit board 500, at the connector end corresponding to one end of the rigid substrate 501, the second layer wirings 508 and 509 are connected perpendicularly to the first layer wirings 506 and 507 respectively.

The printed circuit board 500 can reduce stubs by forming the second wiring 509 with minimized length in the side frame part of the rigid substrate 501, and then the band degradation can be prevented.

Without using the method which lead wirings are formed at the side frame part, there is another method in which lead wiring is led from the connector end. As shown in FIGS. 6 and 7, for example, a printed circuit board 510 includes a card edge connector part 512 at a connector end which is one end of a rigid substrate 511.

The edge connector part 512 includes multiple terminals such as 513, 514, 515, 516, 517, 518, 519, 520, 521 and 522. First layer wirings 523, 524, 525, and 526, which are high frequency signal lines, are connected to the terminals 513, 514, 515, and 516 out of the terminals 513-522 for wiring to each single channel of transmit/receive on the upper layer of the rigid substrate 511.

Second layer wirings 527-532 are connected to the terminals 517-522 out of the terminals 513-522 which form the card edge connector part 512, for wiring to each single channel transmit/receive on the lower layer.

Accordingly, the printed circuit board 510 can reduce stubs by forming the second wirings 527-532 with minimized length in the side frame part of the rigid substrate 511, and then the band degradation can be prevented.

However, if as described above, the method which the lead wiring are led to the side frame part or to the connector end part is applied to an optical transceiver (e.g. CXP transceiver requires 12 channels with differential signals of 10 Gbps), then problems arise as discussed below.

Descriptions will be given first for a case where the lead wiring is led to the frame end part. The problem with respect to this corresponds to a case of the printed circuit board 500 and the wiring method of the printed circuit board shown in FIG. 5.

As shown in FIG. 8, a printed circuit board 540 is provided with a card edge connector part 542 at a connector end which is one end of the rigid substrate 541.

The printed circuit board 540 includes multiple terminals 543-552 forming a card edge connector part 542.

First layer wirings 553-558, which are high frequency signal lines, are disposed up to a central part of the rigid substrate 531 on an upper layer of the rigid substrate 531.

On a lower layer of the rigid substrate 531, a second layer wiring 559 is connected to the first layer wiring 553, a second layer wiring 560 is connected to the first layer wiring 554, a second layer wiring 561 is connected to the first layer wiring 555, and a second layer wiring 562 is connected to the first layer wiring 556. The second layer wirings 559-562 are formed to be perpendicular to the first layer wirings 553-556.

Further, on the lower layer of the rigid substrate 531, a second layer wiring 563 is connected to the first layer wiring 557 and a second layer wiring 564 is connected to the first wiring 558, in which the second layer wirings 563, 564 are formed to be perpendicular to the first layer wirings 557, 558.

Accordingly, when the second layer wiring 564 is led from the first layer wiring 558 disposed at the center part of the rigid substrate 541, the length of the second layer wiring 564 is approximately 1 cm, for example, so that a stub is formed.

Substantial band degradation is caused because of the stub length corresponding to a wavelength (λ/4), in which the corresponding resonance frequency is lowered up to the band frequency range used for signal transmit/receive.

Next, descriptions will be given for the lead wiring which is led to a connector end. The problem here is related to the printed circuit board 510 and the wiring method of the printed circuit board as shown in FIGS. 6 and 7.

As shown in FIG. 9, a printed circuit board 570 includes a card edge connector part 572 at a connector edge that is one end of the rigid substrate 571. The printed circuit board 570 includes multiple terminals 573-582 forming the card edge connector part 572.

On the lower layer of the rigid substrate 571, first layer wirings 583-592, which are high frequency signal lines, are led toward the card edge connector 572.

The printed circuit board 570 has four problems which will be described below. The first one of problems is that impedance mismatching occurs when wiring are formed at right underneath of pads (not shown in the figure) included in the card edge connector part 572.

The second one of problems is that when buried pads are formed in pads of the card edge connector part 572 to shorten the lead wiring, the contacting portions of connectors get degraded and become contactless at dent parts of the buried pads when the connectors are repeatedly used to insert or pull out.

The third one of problems is that when wiring is formed on a card edge substrate 593 having multiple layers such as two layers or seven layers, chamfered parts 594 at insertion side of the card edge substrate 593 expose wiring 595 and 596 as shown in FIG. 10.

Sometimes, this causes wrong alignment order of the contacts when an optical transceiver is connected to the connector.

The fourth one of problems is that even if the problem due to the chamfered parts is solved, when wiring is performed to form four layers or five layers by use of an eight-layer substrate or the like, lead wiring becomes longer, and a stub of approximately 5 mm is remained. Thus band width is affected by the stub.

Patent document 1 shows that removing process can be performed independently on the distance between neighboring contacts, so that one-time milling process can easily remove inside-common plating lead lines independently on the number of contacts.

However, according to patent document 1, a connector edge at one of edges of a substrate is disposed or lead wiring is disposed at the side of a card edge connector, the lead wiring cannot be shortened. As a result, stubs are formed.

On the other hand, patent document 2 shows that a card edge connector having terminals can be certainly manufactured without changing manufacturing process, in which gold plating is performed over the terminals under the same condition.

However, similarly to patent document 1, in patent document 2, as lead wiring are disposed at the connector edge or at the card edge connecter part, the lead wiring cannot be shortened. As a result, stubs are formed.

The present invention is made to solve problems described above. One of objects of the present invention is to provide a printed circuit board and the wiring method of the printed circuit board which prevents degradation of characteristics of transmission path by shortening stubs.

### SUMMARY OF THE INVENTION

A printed circuit board in accordance with the present invention includes a rigid substrate configured to include a card edge connector part to be connected to a host board, a primary signal line configured to be wired to the card edge connector part on the rigid substrate, a connection pad configured to be connected to the primary signal line at an edge opposite to another edge where the card edge connector part is connected, the connection pad being electrically connected to another substrate, and a lead wiring configured to be connected to the connection pad.

A wiring method of a printed circuit board in accordance with the present invention includes wiring a primary signal line to a card edge connector part on a rigid substrate having the card edge connector part, the card edge connector part being connected a host board, and connecting the primary signal line to a connection pad at an edge opposite to another edge to which the card edge connector part is connected, the connection pad being electrically connected to another substrate.

In accordance with a printed circuit board and the wiring method of a printed circuit board, stubs can be shortened so that degradation of characteristics of transmission paths can be prevented.

### BRIEF DESCRIPTION OF THE DRAWINGS

FIG. 1 is a drawing that illustrates a plan view of a printed circuit board and a rigid substrate used in the wiring method of a printed circuit board in accordance with a first embodiment of the present invention;

FIG. 2 is a drawing that illustrates a plan view in which a printed circuit board and a flexible circuit board used in the wiring method of a printed circuit board in accordance with a first embodiment of the present invention are connected;

FIG. 3 is a drawing that illustrates a plan view of a printed circuit board and a rigid substrate used in the wiring method of a printed circuit board in accordance with a second embodiment of the present invention;

FIG. 4 is a drawing that shows a plan view in which a printed circuit board and a flexible circuit board used in the wiring method of a printed circuit board in accordance with a second embodiment of the present invention are connected;

FIG. 5 is a drawing that illustrates a plan view of a printed circuit board and the wiring method of a printed circuit board;

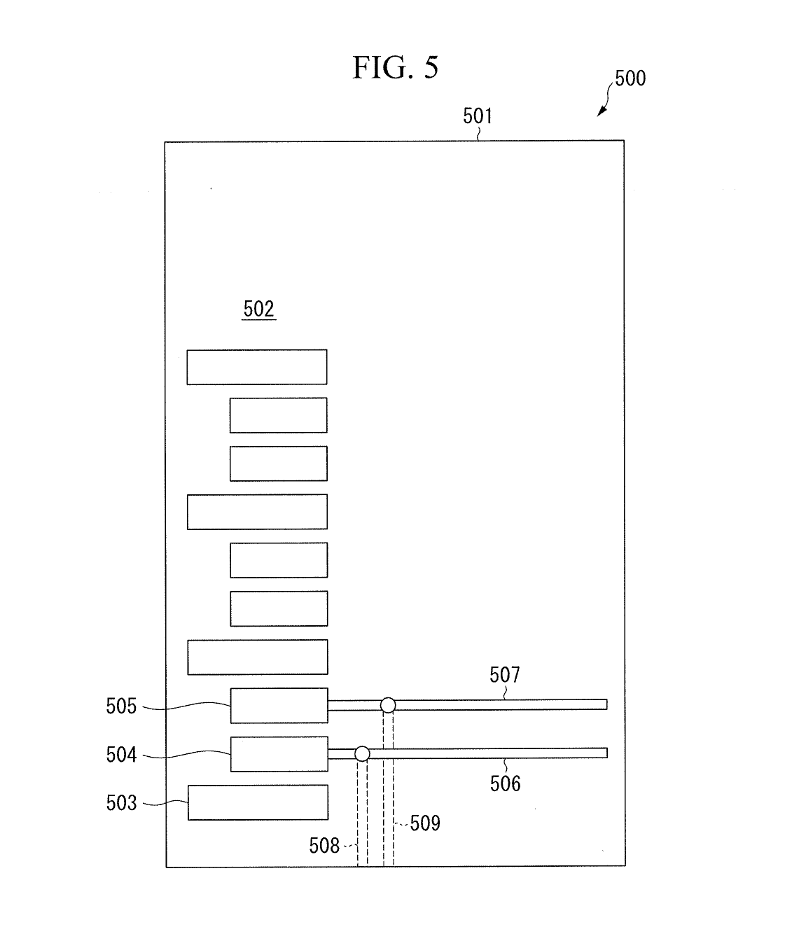

FIG. 6 is a drawing that shows a plan view of a printed circuit board illustrating the wiring method of a printed circuit board that is different from FIG. 5;

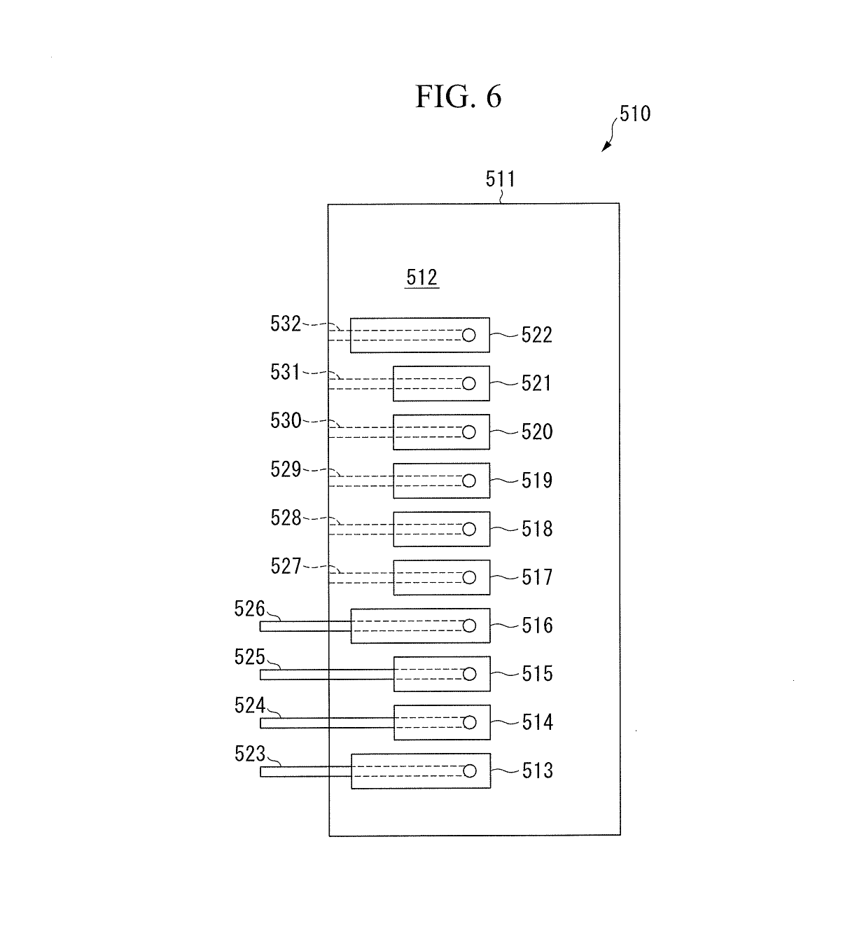

FIG. 7 is a drawing that illustrates a vertical cross-section of a printed circuit board and the wiring method of a printed circuit board in FIG. 6;

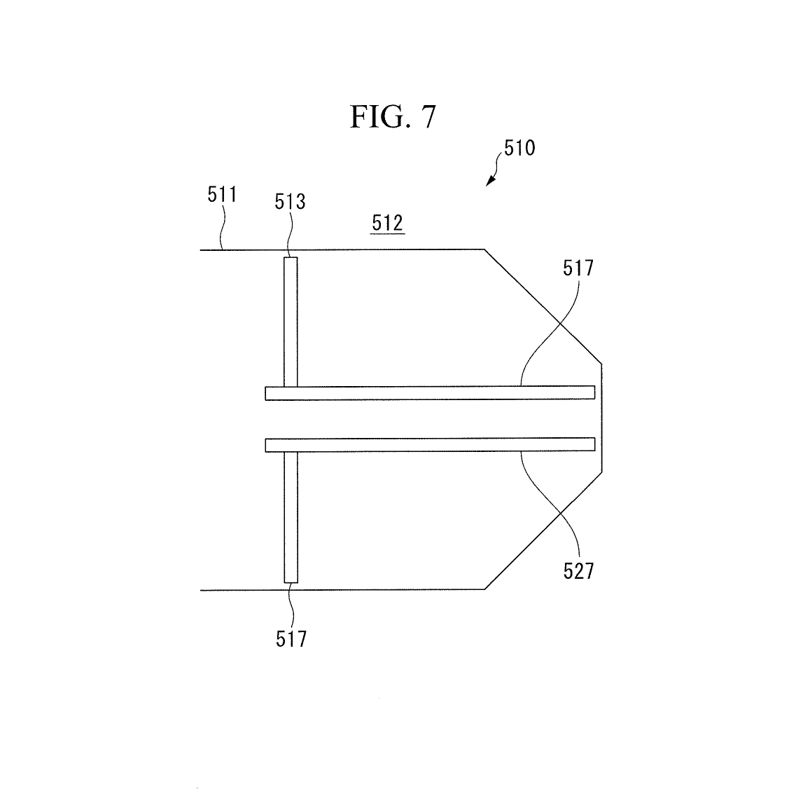

FIG. 8 is a drawing that illustrates a plan view of a printed circuit board and the wiring method of a printed circuit board being different from FIG. 5;

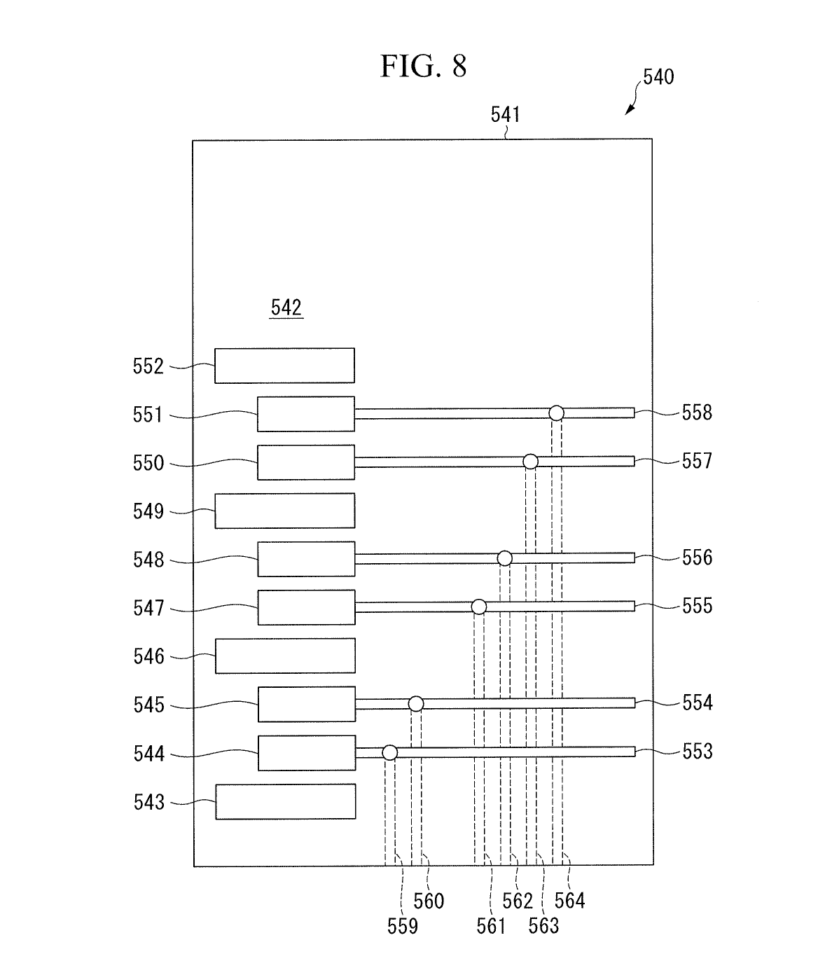

FIG. 9 is a drawing that illustrates a printed circuit board and the wiring method of a printed circuit board that is different from FIG. 8; and

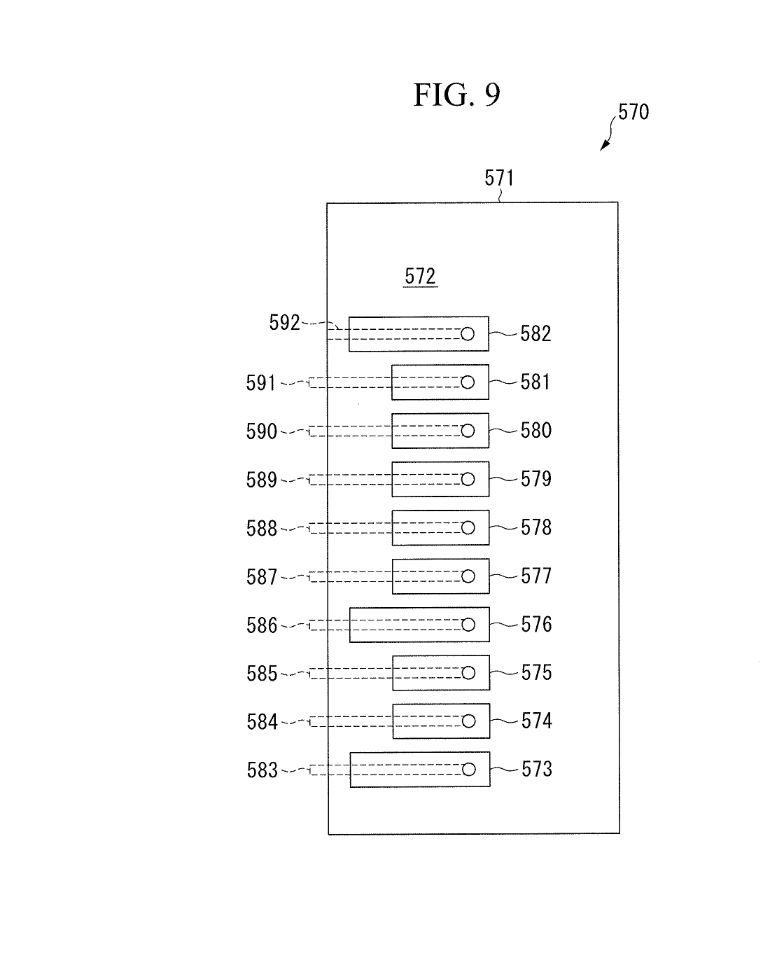

FIG. 10 is a drawing that illustrates a vertical cross-section of a printed circuit board and the wiring method of a printed circuit board being different from FIG. 9.

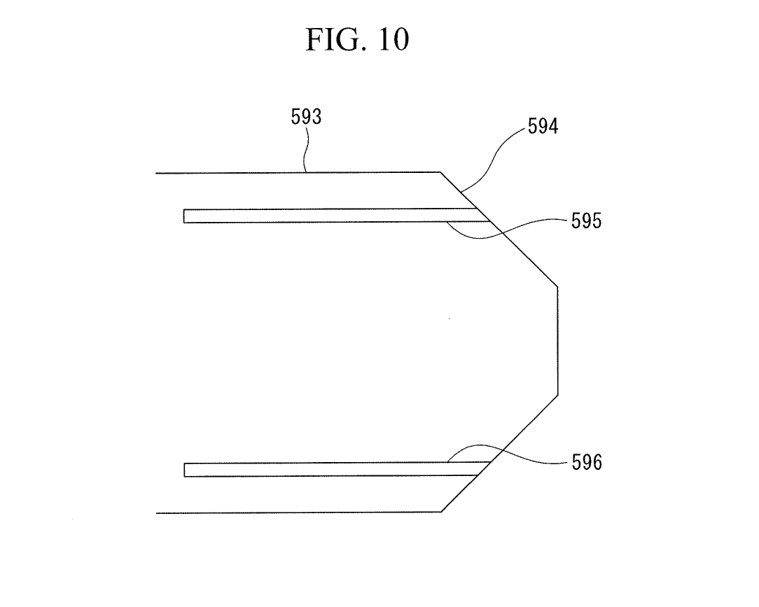

### DETAILED DESCRIPTION OF EXEMPLARY EMBODIMENTS

In the following, descriptions will be given for a printed circuit board and the wiring method of a printed circuit board in accordance with multiple embodiments referring to drawings.

### First Embodiment

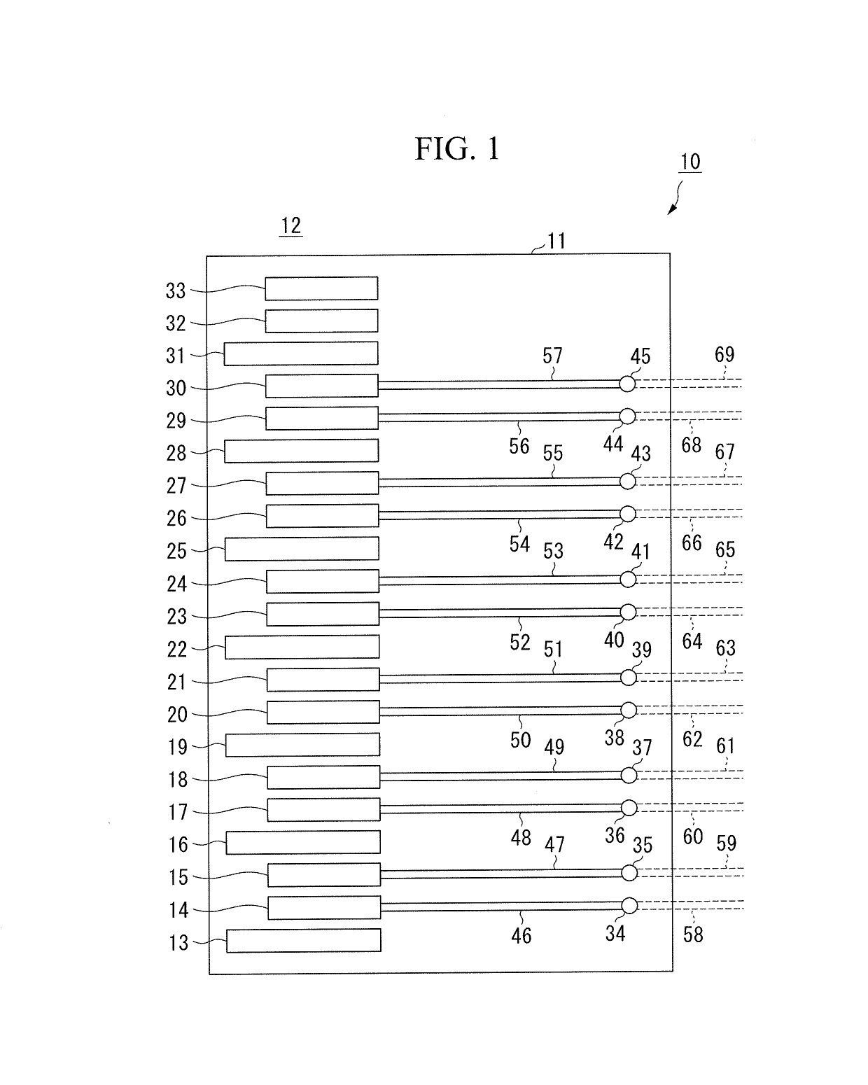

A printed circuit board 10 in accordance with a first embodiment of the present invention includes a rigid substrate 11 as shown in FIG. 1.

The rigid substrate 11 includes a card edge connector part 12 to be connected to a host board (not shown in the figure) at a side end of the rigid substrate 11.

For example, twenty one terminals (13-33) are provided on the card edge connector part 12.

Connection pads 34-45 are formed, for example, at positions approximately 1 to 2 mm apart from an end of the connectors, in which the end of the connector is one end of the rigid substrate 11 opposite to the card edge connector part 12.

Here, the connection pads 34-45 are disposed to correspond to the terminals 14-30, respectively. More specifically, the connection pad 34 is disposed to correspond to the terminal 14. Further, the connection pad 35-45 are disposed to correspond to terminals 15, 17, 18, 20, 21, 23, 24, 26, 27, 29, and 30, respectively.

On the upper layer of the rigid substrate 11, the terminals 14-30 with the exception of 16, 19, 22, 25 and 28 are connected to the connection pads 34-45 via primary signal lines 46-57. More specifically, the primary signal line 46 connects the terminal 14 and the connection pad 34. The primary signal line 47 connects the terminal 15 and the connection pad 35. The primary signal line 48 connects the terminal 17 and the connection pad 36. The primary signal line 49 connects the terminal 18 and the connection pad 37. The primary signal line 50 connects the terminal 20 and the connection pad 38. The primary signal line 51 connects the terminal 21 and the connection pad 39. The primary signal line 52 connects the terminal 23 and the connection pad 40. The primary signal line 53 connects the terminal 24 and the connection pad 41. The primary signal line 54 connects the terminal 26 and the connection pad 42. The primary signal line 55 connects the terminal 27 and the connection pad 43. The primary signal line 56 connects the terminal 29 and the connection pad 44. The primary signal line 57 connects the terminal 30 and the connection pad 45.

On the lower layer of the rigid substrate 11, the connection pads 34-45 are connected to lead wiring 58-69, respectively. More specifically, the lead wiring 58 is connected to the connection pad 34. The lead wiring 59 is connected to the connection pad 35. The lead wiring 60 is connected to the connection pad 36.

The lead wiring 61 is connected to the connection pad 37. The lead wiring 62 is connected to the connection pad 38. The lead wiring 63 is connected to the connection pad 39. The lead wiring 64 is connected to the connection pad 40. The lead wiring 65 is connected to the connection pad 41. The lead wiring 66 is connected to the connection pad 42. The lead wiring 67 is connected to the connection pad 43. The lead wiring 68 is connected to the connection pad 44. The lead wiring 69 is connected to the connection pad 45.

In this case, the lead wiring 58-69 are positioned on the lower layer of the rigid substrate 11, in which the lower layer is positioned lower than a plane (surface) forming the card edge connector part 12 that is located at a side part of the rigid substrate 11.

The lead wiring 58-69 are connected to the connection pads 34-45 and formed so as to extend toward the extension directions of the primary signal lines 46-57. The lead wiring 58-69 do not intersect the primary signal lines 46-57. The lead wiring 58-69 are led out from a connecter end that is one end of the rigid substrate 11 being opposite to the card edge connector part 12 of the rigid substrate 11.

As the lead wiring 58-69 are led out from the connecter end that is one end of the rigid substrate 11 being opposite to the card edge connector part 12 of the rigid substrate 11, the lengths of the lead wiring 58-69 can be uniform and shortened compared to a case where the lead wirings 58-69 are bent.

Thus, the lead wirings 58-69 can be set up to have lengths less than or equal to 1 mm being led out from the one end of the rigid substrate 11 opposite to the card edge connector part 12.

Next, descriptions will be given for a wiring method of the printed circuit board 10.

At a connector end which is one end of the rigid substrate 11, the card edge connector part 12 having twenty one terminals (13-33), is formed. Then, the connection pads 34-45 are formed at one end of the rigid substrate 11 being opposite to the card edge connector part 12. The connection pads 34-45 are located at approximately 1 to 2 mm from the edge of the connector end.

On the upper layer of the rigid substrate 11, the primary signal lines 46-57 are formed to connect the terminals 14-30 (except for terminals 16, 19, 22, 25 and 28) and the connection pads 34-45.

Subsequently, on the lower layer of the rigid substrate 11, the lead wiring 58-69 are connected to the connection pads 34-45.

Descriptions will be given for a case where a flexible circuit board is connected to the printed circuit board 10.

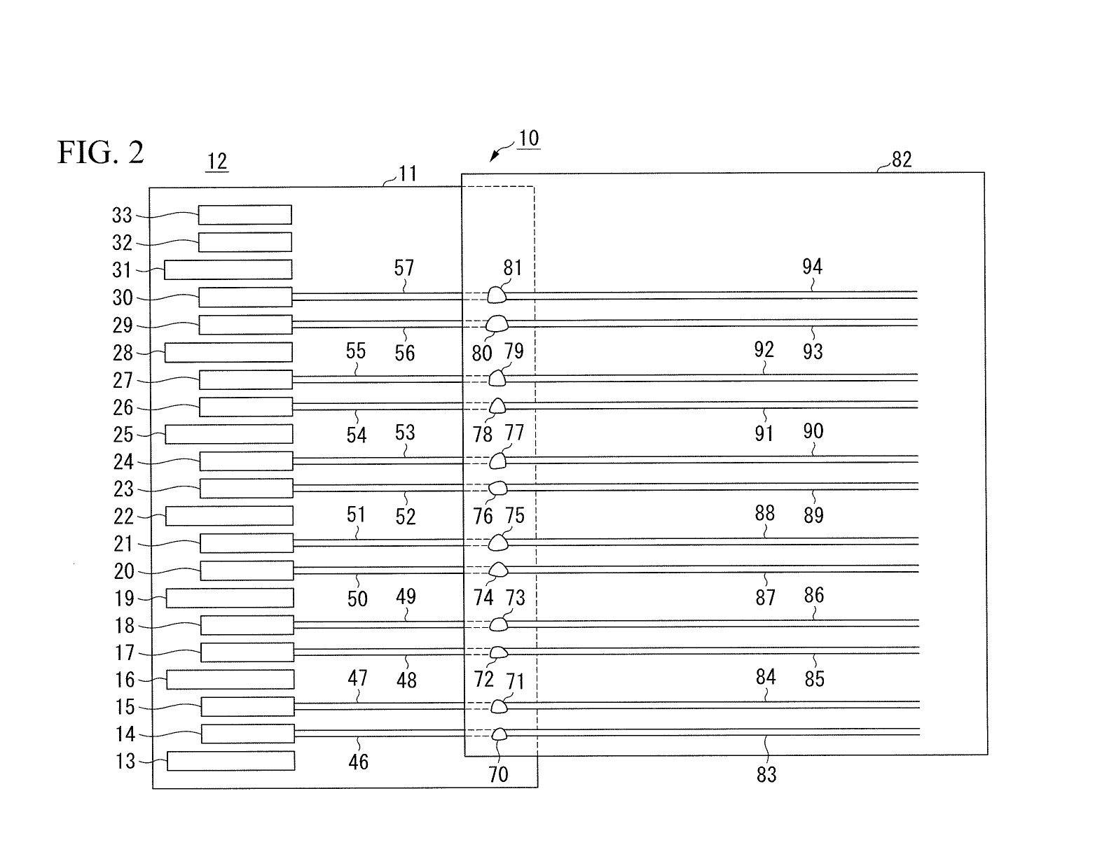

As shown in FIG. 2, solder balls 70-81 are formed on the connection pads 34-45 of the printed circuit board 10.

A flexible circuit board 82 includes primary signal lines 83-94. The primary signal lines 83-94 are connected with the solder balls 70-81 by performing a reflow soldering process.

In this manner, the flexible circuit board 82 can be accurately connected between the substrates at a time by the reflow soldering process even if there are a lot of terminals (pins) to be connected and it is difficult to connect with the substrate by use of a soldering iron or the like by visual handling.

For example, a soldering iron is usually used for connecting TOSA, ROSA (E/O, O/E conversion modules) or the like. As optical transceivers include multiple-channel soldering connections, fine-pitch soldering connection such as for BGA pad is performed.

Even for such a soldering process, the reflow soldering process can greatly reduce the man-hours of a mounting process and perform a high accuracy mounting process.

As described above, in accordance with the printed circuit board 10 of a first embodiment of the present invention, the lead wiring 58-69 are connected to the connection pads 34-45. The lead wiring 58-69 are formed so as to extend toward the extension directions of the primary signal lines 46-57. The lead wiring 58-69 are pulled out not so as to intersect the primary signal lines 46-57.

Accordingly, the printed circuit board 10 allows designing the lengths of the lead wiring 58-69 less than or equal to 1 mm, and then the length of stubs can be shortened and the degradation of characteristics of transmission paths can be avoided.

In accordance with the printed circuit board 10 of the first embodiment, the lead wiring 58-69 are connected to the connection pads 34-45, and formed to extend toward the extension direction of the primary signal lines 46-57. The lead wiring 58-69 are pulled out from the connector end that is one end of the rigid substrate 11 being opposite to the card edge connector part 12 without intersecting the primary signal lines 46-57.

Accordingly, the printed circuit board 10 allows designing the lead wiring 58-69 to be pulled out from the connector end that is one end of the rigid substrate 11 opposite to the card edge connector part 12, and the lead wiring 58-69 are designed to be formed less than or equal to 1 mm. Thereafter, the length of stubs can be shortened and the degradation of characteristics of transmission path can be avoided.

In accordance with the printed circuit board 10 of the first embodiment of the present invention, the flexible circuit board 82 can be accurately connected with a substrate at a time by the reflow soldering process even if there are a lot of terminals (pins) to be connected and it is difficult to connect between substrates by use of a soldering iron or the like by visual handling.

The printed circuit board 10 allows the design of the lead wiring 58-69 to be less than or equal to 1 mm, and the length of stubs can be shortened and the degradation of characteristics of transmission routes can be avoided.

### Second Embodiment

In the following, descriptions will be given for a printed circuit board and a wiring method of the printed circuit board in accordance with a second embodiment of the present invention.

In the descriptions with respect to the second embodiment, configuration elements and functional elements identical or similar to those described in the first embodiment will be assigned the same symbols or corresponding symbols, and thus the descriptions about them will be omitted.

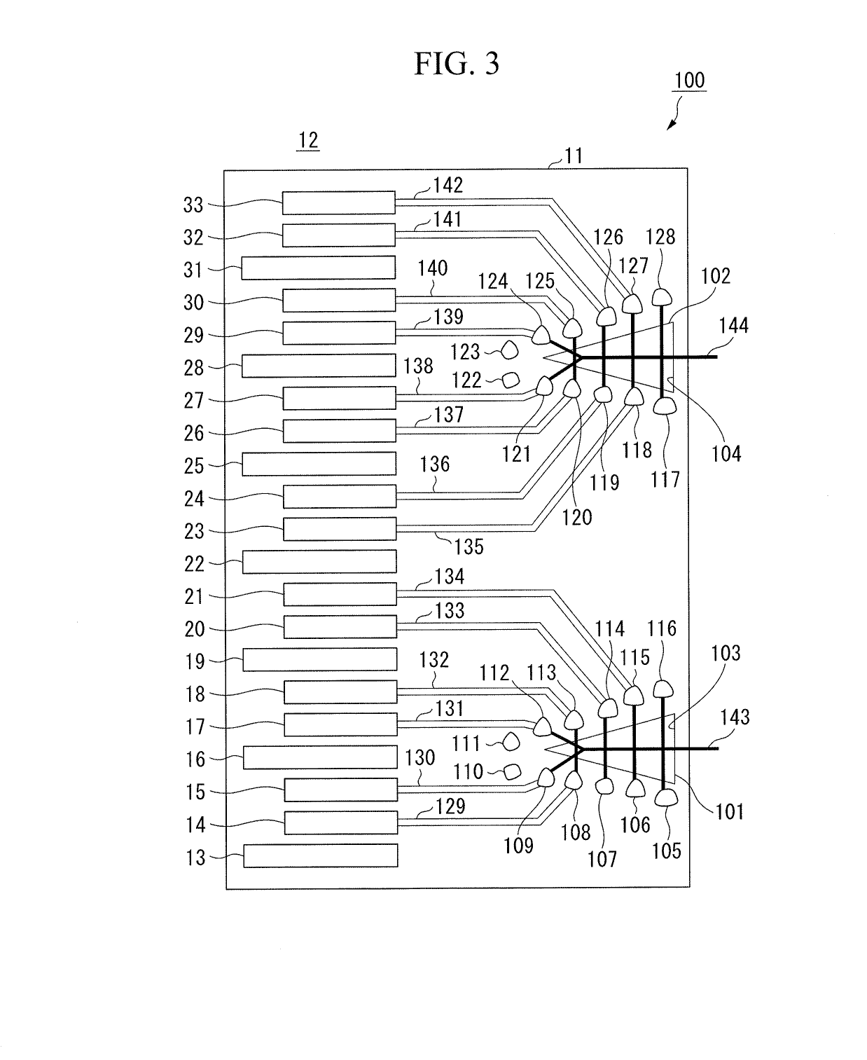

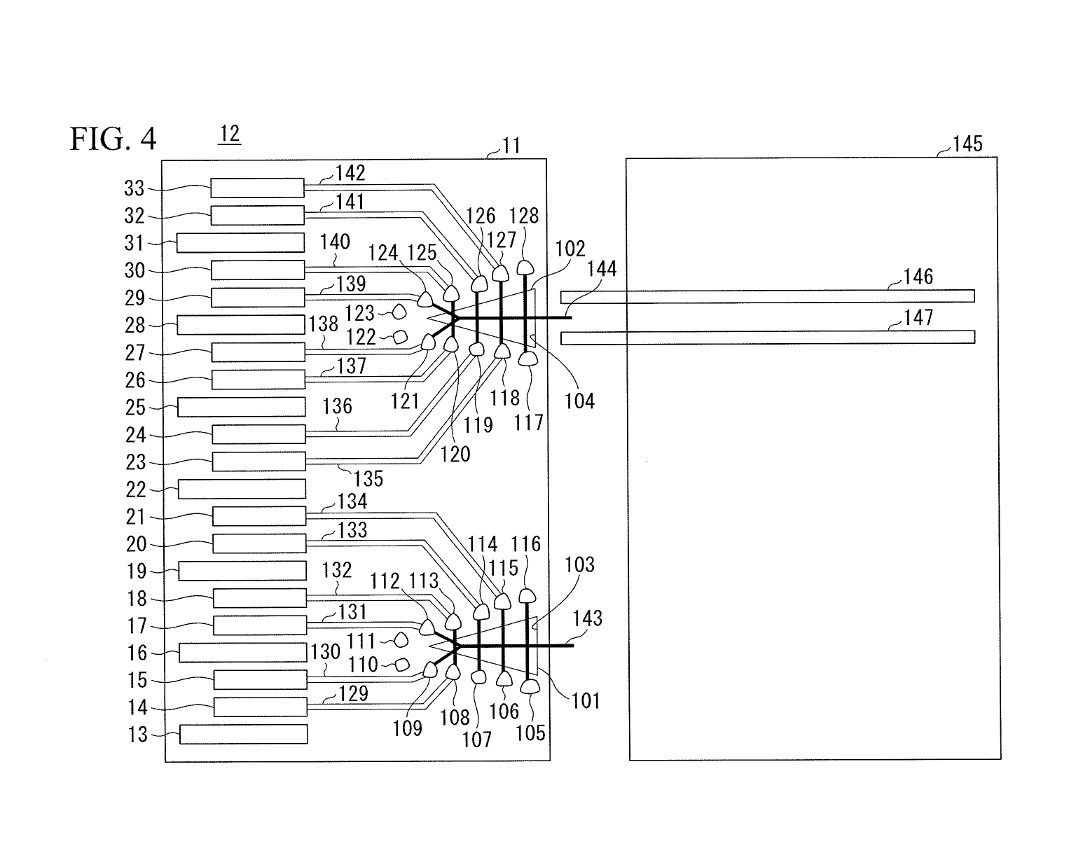

As shown in FIG. 3, a printed circuit board 100 in accordance with the second embodiment of the present invention includes so many primary signal lines such as CXP, in which approximately sixty of the primary signal lines are included in CXP. FIG. 4 is a drawing that shows a plan view in which a printed circuit board and a flexible circuit board used in the wiring method of a printed circuit board in accordance with a second embodiment of the present invention are connected.

In this case, due to the limitation of the size of a rigid substrate 11, connection pads cannot be arranged on the edge part of the rigid substrate 11. In the case of the printed circuit board 100 in accordance with the second embodiment, for example, twenty one terminals, being terminal 13-33, are disposed at a card edge connector part 12 at an end side of the rigid substrate 11.

In the printed circuit board 100, multiple dig holes such as dig holes 101 and 102 are formed near the connector edge that is one of edges of the rigid substrate 11 opposite to the card edge connector part 12.

The dig holes 101 and 102 are formed by digging out triangular areas in a thickness direction of the rigid substrate 11, in which lead wiring storage parts 103 and 104 are formed inside of the dig holes 101 and 102.

Multiple connection pads 105-116 are formed in a V-shape around the edges of the dig hole 101.

Multiple connection pads 117-128 are formed in a V-shape around the edges of the dig hole 102.

A primary signal line 129 is formed to connect a terminal 14 and a connection pad 108, and a primary signal line 130 is formed to connect a terminal 15 and a connection pad 109.

A primary signal line 131 is formed to connect a terminal 17 and a connection pad 112, and a primary signal line 132 is formed to connect a terminal 18 and a connection pad 113.

A primary signal line 133 is formed to connect a terminal 20 and a connection pad 114, and a primary signal line 134 is formed to connect a terminal 21 and a connection pad 115.

A primary signal line 135 is formed to connect a terminal 23 and a connection pad 118, and a primary signal line 136 is formed to connect a terminal 24 and a connection pad 119.

A primary signal line 137 is formed to connect a terminal 26 and a connection pad 120, and a primary signal line 138 is formed to connect a terminal 27 and a connection pad 121.

A primary signal line 139 is formed to connect a terminal 29 and a connection pad 124, and a primary signal line 140 is formed to connect a terminal 30 and a connection pad 125.

A primary signal line 141 is formed to connect a terminal 32 and a connection pad 126, and a primary signal line 142 is formed to connect a terminal 33 and a connection pad 127.

Accordingly, a lead wiring 143 is connected to connection pads 108, 109 and 112-115 around the dig hole 101, and a lead wiring 144 is connected to connection pads 118-121 and 124-127 around the dig hole 102.

After the lead wiring 143 is connected to the connection pads 108, 109 and 112-115, and after the lead wiring 144 is connected to the connection pads 118-121 and 124-127, a plating process is performed.

Subsequently, after the plating process is performed, the dig holes 101 and 102 are formed by substrate processing.

In this manner, the length of edges of the rigid substrate 11 is substantially increased due to the dig holes 101 and 102.

Therefore, as the lead wirings 143 and 144 are connected in the areas of the dig holes 101 and 102, the lengths of the lead wirings 143 and 144 can be set less than or equal to 1 mm.

Next, descriptions will be given for a case where a flexible substrate is connected with the printed circuit board 100.

Solder balls (not shown in the figure) are provided on the connection pads 105-116 on the printed circuit board 100. By performing a reflow soldering process, primary signal lines 146 and 147 included in a flexible substrate 145 are respectively connected to the lead wiring 144 out of lead wirings 143 and 144. Further, a primary signal line (not shown in the figure) is connected to the lead wiring 143.

The printed circuit board 100 and the wiring method of a printed circuit board in accordance with the second embodiment, the dig holes 101 and 102 are formed in the rigid substrate 11, and the connection pads 105-116 are formed around the areas of the dig holes 101 and 102.

Thereby, based on the printed circuit board 100 and the wiring method of a printed circuit board in accordance with the second embodiment, the connection process of the lead wirings 143 and 144 and the primary signal lines 146 and 147 are performed around the areas of the dig holes 101 and 102.

In accordance with the printed circuit board 100 and the wiring method of the printed circuit board, the lead wirings 143 and 144 can be designed to be less than or equal to 1 mm.

The printed circuit board and the wiring method of the printed circuit board in accordance with the present invention are not limited to the embodiments described above, and further, properly variations, reformations or the like can be performed.

As described above, based on the printed circuit board and the wiring method of the printed circuit board in accordance with the present invention, the length of stubs can be shortened, and thus the degradation of characteristics of transmission routes can be avoided.

Based on the descriptions above, in particular, with respect to a card edge type optical transceiver, the printed circuit board and the wiring method of the printed circuit board in accordance with the present invention are useful for applying to parts which require thick gold plating (electrical gold plating) such as card edge connector parts. As the printed circuit board and the wiring method of the printed circuit board in accordance with the present invention can protect gold plating and prevent the degradation of characteristics, the industrial availability of the present invention is quite large.

While preferred embodiments of the invention have been described and illustrated above, it should be understood that these are examples of the invention and are not to be considered as limiting. Additions, omissions, substitutions, and other modifications can be made without departing from the scope of the present invention.

Accordingly, the invention is not to be considered as being limited by the foregoing description, and is only limited by the scope of the appended claims.

What is claimed is:

1. A printed circuit board comprising:
a rigid substrate configured to include a card edge connector part to be connected to a host board;
a primary signal line configured to be wired to the card edge connector part on the rigid substrate;
a connection pad configured to be connected to the primary signal line at an edge opposite to another edge where the card edge connector part is connected, the connection pad being electrically connected to another substrate; and
a lead wiring configured to be connected to the connection pad.

2. The printed circuit board as claimed in claim 1, wherein the lead wiring is disposed at an opposite side to the card edge connector part on the rigid substrate.

3. The printed circuit board as claimed in claim 1, wherein a solder ball is formed on the connection pad, and another primary signal line included on a flexible substrate is connected to the primary signal line of the rigid substrate through the solder ball.

4. The printed circuit board as claimed in claim 1, wherein a dig hole is formed in the rigid substrate and the connection pad is disposed around the dig hole.

5. A wiring method of a printed circuit board, comprising:
wiring a primary signal line to a card edge connector part on a rigid substrate having the card edge connector part, the card edge connector part being connected a host board; and
connecting the primary signal line to a connection pad at an edge opposite to another edge to which the card edge connector part is connected, the connection pad being electrically connected to another substrate.
